(19) United States
(12) Patent Application Publication
(10) Pub. No.: US 2026/0304622 A1
(43) Pub. Date: Oct. 1, 2026

(54) WIRING SUBSTRATE

(71) Applicant: Shinko Electric Industries Co., LTD., Nagano-shi (JP)

(72) Inventor: Takashi Nishiyama, Nagano-shi (JP)

(73) Assignee: Shinko Electric Industries Co., LTD., Nagano-shi (JP)

(21) Appl. No.: 19/578,158

(22) Filed: Mar. 25, 2026

(30) Foreign Application Priority Data
Mar. 27, 2025 (JP) 2025-053381

(51) Int. Cl. H05K 1/11; H05K 1/02

(52) U.S. Cl. CPC H05K 1/115; H05K 1/0298; H05K 2201/096

(57) ABSTRACT

A wiring substrate includes a first wiring layer, a first insulating layer covering the first wiring layer, a first through hole extending through the first insulating layer, a first via wiring having a landless structure and filling the first through hole, a first recess formed in the first via wiring, a second insulating layer filling the first recess, a second recess formed in the second insulating layer and overlapping the first recess in plan view, a second through hole extending from the second recess to the first recess, a second via wiring filling the second through hole, a second wiring layer formed on the second recess, and a third wiring layer formed on the second insulating layer. The second via wiring has a smaller planar size than the first via wiring. The second wiring layer has an upper surface located downward from an upper surface of the third wiring layer.

### CROSS-REFERENCE TO RELATED APPLICATIONS

This application is based upon and claims the benefit of priority from Japanese Patent Application No. 2025-053381, filed on Mar. 27, 2025, the entire contents of which are incorporated herein by reference.

### BACKGROUND

### 1. Field

This disclosure relates to a wiring substrate and a method for manufacturing a wiring substrate.

### 2. Description of Related Art

Wiring substrates for mounting electronic components, such as semiconductor elements, are available in various shapes and structures. JP2023-183674A discloses an example of a typical wiring substrate. This wiring substrate includes a stacked via structure in which a second via wiring is formed on a first via wiring having a landless structure.

### SUMMARY

In such a wiring substrate, there is a demand for improvement in the reliability of electrical connection.

In one general aspect, a wiring substrate includes a first wiring layer, a first insulating layer covering an upper surface and a side surface of the first wiring layer, a first through hole extending through the first insulating layer in a thickness-wise direction and exposing part of the upper surface of the first wiring layer, a first via wiring having a landless structure and filling the first through hole, a first recess formed in an upper surface of the first via wiring and recessed downward from an upper surface of the first insulating layer, a second insulating layer formed on the upper surface of the first insulating layer and filling the first recess, a second recess formed in an upper surface of the second insulating layer and overlapping the first recess in plan view, a second through hole extending from the second recess to the first recess, a second via wiring filling the second through hole, a second wiring layer formed on a wall surface of the second recess and formed integrally with the second via wiring, and a third wiring layer formed on the upper surface of the second insulating layer. The second via wiring has a smaller planar size than the first via wiring. The second wiring layer has an upper surface located downward from an upper surface of the third wiring layer.

Other features and aspects will be apparent from the following detailed description, the drawings, and the claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a schematic cross-sectional view of a wiring substrate in accordance with an embodiment.

FIG. 2 is an enlarged partial cross-sectional view of the wiring substrate illustrated in FIG. 1.

FIGS. 3, 4, 5, 6, 7, 8, 9, 10, 11, 12, 13, 14, 15, 16, 17, and 18 are schematic cross-sectional views illustrating a method for manufacturing the wiring substrate illustrated in FIG. 1.

FIG. 19 is a schematic cross-sectional view of a wiring substrate of a comparative example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

An embodiment will now be described with reference to the accompanying drawings.

The drawings may not be drawn to scale, and the relative size, proportions, and depiction of elements may be exaggerated for clarity, illustration, or convenience. To facilitate understanding, hatching lines may not be illustrated or may be replaced by shadings in the cross-sectional drawings. In this specification, the terms “vertical direction” and “sideward direction” correspond to directions when the drawings are oriented to an appropriate position that allows reference numerals of the elements to be read correctly. Further, unless otherwise specified, a numerical range of “X1 to X2,” defined by the upper limit value X1 and the lower limit value X2, refers to a range that is greater than or equal to X1 and less than or equal to X2.

### Overall Structure of Wiring Substrate 10

A wiring substrate 10 includes a core substrate 20, a first wiring structure 30, a second wiring structure 40, a third wiring structure 50, a solder resist layer 60, and a solder resist layer 61. The first wiring structure 30, the second wiring structure 40, and the solder resist layer 60 are arranged at one side of the core substrate 20. The third wiring structure 50 and the solder resist layer 61 are arranged at the other side of the core substrate 20.

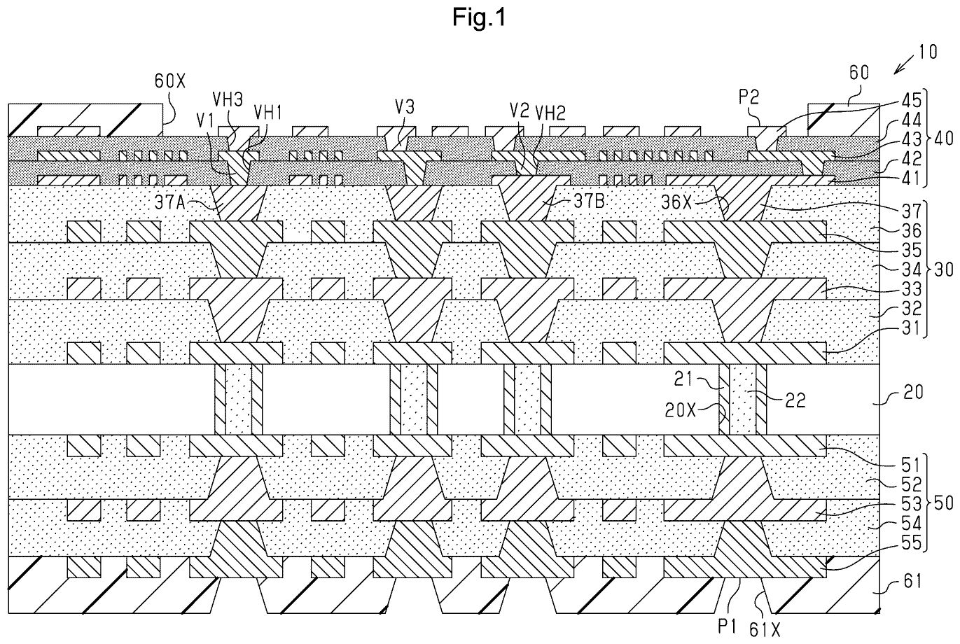

In the present embodiment, for the sake of convenience, as viewed in FIG. 1, the side of the wiring substrate 10 at which the solder resist layer 60 is located will be referred to as “one side” or “the upper side”, and the side of the wiring substrate 10 at which the solder resist layer 61 is located will be referred to as “the other side” or “the lower side”. Further, in the present embodiment, for the sake of convenience, a surface of each element facing the solder resist layer 60 will be referred to as “one surface” or “the upper surface”, and another surface of each element facing the solder resist layer 61 will be referred to as “the other surface” or “the lower surface”. The wiring substrate 10 may be used in a state flipped upside down or may be arranged at any angle. In this specification, unless otherwise specified, the term “plan view” refers to a view of a subject taken in a normal direction of one surface of the solder resist layer 60. Further, in this specification, unless otherwise specified, the term “planar shape” refers to a shape of a subject as viewed in a normal direction of one surface of the solder resist layer 60.

### Structure of Core Substrate 20

The core substrate 20 may be, for example, a glass epoxy substrate in which a glass cloth is impregnated with a thermosetting insulating resin, such as an epoxy-based resin, or the like. The core substrate 20 may be, for example, a substrate in which a woven cloth or non-woven cloth of glass fibers, carbon fibers, aramid fibers, or the like, is impregnated with a thermosetting insulating resin, such as an epoxy-based resin or the like. The glass cloth and the like are not illustrated in the drawings.

The core substrate 20 includes through holes 20X extending through the core substrate 20 in a thickness-wise direction. A through-electrode 21 extending through the core substrate 20 in the thickness-wise direction is formed on a wall surface of each through hole 20X. The central part of each through hole 20X, that is, the inner side of the through-electrode 21 in each through hole 20X, is filled with a resin 22. The material of the through-electrode 21 may be, for example, copper (Cu) or a copper alloy. The material of the resin 22 may be, for example, an insulating resin, such as an epoxy-based resin or the like.

### First Wiring Structure 30

The first wiring structure 30 is formed on the upper surface of the core substrate 20. The first wiring structure 30 of the present embodiment is formed by sequentially stacking a wiring layer 31, an insulating layer 32, a wiring layer 33, an insulating layer 34, a wiring layer 35, an insulating layer 36, and a wiring layer 37, on the upper surface of the core substrate 20.

The material of the wiring layers 31, 33, 35, and 37 may be, for example, copper or a copper alloy. The line/space (L/S) of the wiring layers 31, 33, and 35 may be, for example, approximately 10 μm/10 μm to 50 μm/50 μm. The “line” in “line/space” indicates the width of wiring, and the “space” indicates the distance (wiring interval) between adjacent wiring parts. For example, when the line/space is 10 μm/10 μm to 50 μm/50 μm, the wiring width is 10 μm or greater and 50 μm or less, and the wiring interval is 10 μm or greater and 50 μm or less. The wiring width does not have to be equal to the wiring interval.

The insulating layers 32, 34, and 36 are insulating layers including a non-photosensitive resin as a main component. The main component of the insulating layers 32, 34, and 36 may be, for example, a thermosetting non-photosensitive resin, such as an epoxy-based resin, an imide-based resin, a phenol-based resin, a cyanate-based resin, or the like. The insulating layers 32, 34, and 36 may contain, for example, a filler, such as silica, alumina, or the like. The insulating layers 32, 34, and 36 are, for example, each thinner than the core substrate 20. The insulating layers 32, 34, and 36 may each have a thickness of, for example, approximately 30 μm to 70 μm. The insulating layers 32, 34, and 36 may have the same thickness or different thicknesses.

The wiring layer 31 is formed on the upper surface of the core substrate 20. The wiring layer 31 is electrically connected to the through-electrodes 21. The insulating layer 32 is formed on the upper surface of the core substrate 20 to cover the wiring layer 31. The wiring layer 33 is formed on the upper surface of the insulating layer 32. For example, the wiring layer 33 is formed integrally with via wiring extending through the insulating layer 32 in the thickness-wise direction, and is electrically connected to the wiring layer 31 by the via wiring. The insulating layer 34 is formed on the upper surface of the insulating layer 32 to cover the wiring layer 33. The wiring layer 35 is formed on the upper surface of the insulating layer 34. For example, the wiring layer 35 is formed integrally with via wiring extending through the insulating layer 34 in the thickness-wise direction, and is electrically connected to the wiring layer 33 by the via wiring.

The insulating layer 36 is formed on the upper surface of the insulating layer 34 to cover the wiring layer 35. Through holes 36X extend through the insulating layer 36 in the thickness-wise direction at given locations of the insulating layer 36, and expose parts of the upper surface of the wiring layer 35. The through holes 36X are each tapered to have a diameter (opening width) that decreases from the upper side (closer to wiring layer 40) toward the lower side (closer to wiring layer 20) in FIG. 1. Each through hole 36X has a shape of, for example, an inverted truncated cone so that the upper open end has a larger diameter than the lower open end. The diameter of the upper open end of the through hole 36X may be, for example, approximately 100 μm to 150 μm.

The wiring layer 37 is via wiring embedded in the insulating layer 36. The wiring layer 37 is via wiring filling the through holes 36X of the insulating layer 36. The wiring layer 37 is shaped in conformance with the through holes 36X. The wiring layer 37 is tapered to have a diameter that decreases from the upper side (closer to wiring layer 40) toward the lower side (closer to wiring layer 20) in FIG. 1. The wiring layer 37 has a shape of, for example, an inverted truncated cone so that the upper surface has a larger diameter than the lower surface. The diameter of the upper surface of the wiring layer 37 may be, for example, approximately 100 μm to 150 μm.

The wiring layer 37 includes a first via wiring 37A having a landless structure, which does not include a land pattern. Further, the wiring layer 37 may include a first via wiring 37B connected to the wiring layer 41, which includes a land pattern. The wiring layer 41 is a wiring layer included in the second wiring structure 40. In this manner, in the wiring substrate 10 of the present embodiment, the first via wiring 37A having a landless structure is mixed with the first via wiring 37B having a land.

### Third Wiring Structure 50

The third wiring structure 50 is formed on the lower surface of the core substrate 20. The third wiring structure 50 of the present embodiment is formed by sequentially stacking a wiring layer 51, an insulating layer 52, a wiring layer 53, an insulating layer 54, and a wiring layer 55, on the lower surface of the core substrate 20.

The material of the wiring layers 51, 53, and 55 may be, for example, copper or a copper alloy. The wiring layers 51, 53, and 55 may each have a thickness of, for example, approximately 8 μm to 35 μm. The line/space (L/S) of the wiring layers 51, 53, and 55 may be, for example, approximately 10 μm/10 μm to 50 μm/50 μm.

The insulating layers 52 and 54 are insulating layers including a non-photosensitive resin as a main component. The main component of the insulating layers 52 and 54 may be, for example, a thermosetting non-photosensitive resin, such as an epoxy-based resin, an imide-based resin, a phenol-based resin, a cyanate-based resin, or the like. The insulating layers 52 and 54 may contain, for example, a filler, such as silica, alumina, or the like. The thickness of each of the insulating layers 52 and 54 may be, for example, equal to the thickness of each of the insulating layers 32, 34, and 36 or greater than the thickness of each of the insulating layers 32, 34, and 36. The insulating layers 52 and 54 are, for example, each thinner than the core substrate 20. The insulating layers 52 and 54 may each have a thickness of, for example, approximately 35 μm to 100 μm. The insulating layers 52 and 54 may have the same thickness or different thicknesses.

The wiring layer 51 is formed on the lower surface of the core substrate 20. The wiring layer 51 is electrically connected to the wiring layer 31 by the through-electrodes 21. The insulating layer 52 is formed on the lower surface of the core substrate 20 to cover the wiring layer 51. The wiring layer 53 is formed on the lower surface of the insulating layer 52. For example, the wiring layer 53 is formed integrally with via wiring extending through the insulating layer 52 in the thickness-wise direction, and is electrically connected to the wiring layer 51 by the via wiring. The insulating layer 54 is formed on the lower surface of the insulating layer 52 to cover the wiring layer 53. The wiring layer 55 is formed on the lower surface of the insulating layer 54. For example, the wiring layer 55 is formed integrally with via wiring extending through the insulating layer 54 in the thickness-wise direction, and is electrically connected to the wiring layer 53 by the via wiring.

### Structure of Solder Resist Layer 61

The solder resist layer 61 is the outermost insulating layer (here, lowermost insulating layer) of the wiring substrate 10. The solder resist layer 61 is formed on the lower surface of the third wiring structure 50. In the example illustrated in FIG. 1, the solder resist layer 61 is formed on the lower surface of the insulating layer 54, which is the lowermost insulating layer of the third wiring structure 50, and covers the wiring layer 55, which is the lowermost wiring layer of the third wiring structure 50. The solder resist layer 61 is an insulating layer including a photosensitive resin as a main component. The material of the solder resist layer 61 may be, for example, a photosensitive insulating resin including a phenol-based resin, a polyimide-based resin, or the like, as a main component. The solder resist layer 61 may include, for example, a filler, such as silica, alumina, or the like.

The solder resist layer 61 includes openings 61X that expose parts of the lower surface of the lowermost wiring layer 55 as external connection pads P1. The external connection pads P1 are connected to external connection terminals when mounting the wiring substrate 10 on a mounting substrate, such as a motherboard or the like.

A surface-processed layer may be formed on the wiring layer 55 exposed from the openings 61X. The surface-processed layer may be an Au layer, an Ni layer/Au layer (metal layer formed by stacking an Ni layer and an Au layer in this order), an Ni layer/Pd layer/Au layer (metal layer formed by stacking an Ni layer, a Pd layer, and an Au layer in this order), or the like. The Au layer is a metal layer formed from Au or an Au alloy. The Ni layer is a metal layer formed from Ni or an Ni alloy. The Pd layer is a metal layer formed from Pd or a Pd alloy. The Au layer, the Ni layer, and the Pd layer may each be, for example, an electroless plating layer formed by electroless plating. Alternatively, the surface-processed layer may be an organic solderability preservative (OSP) film formed by performing an oxidation-resisting process, such as an OSP process, on the surface of the external connection pads P1. The OSP film may be, for example, an organic coating of an azole compound, an imidazole compound, or the like. The wiring layer 55 exposed from the openings 61X (or surface-processed layer formed on wiring layer 55) may be used as external connection terminals.

The external connection pads P1 and the openings 61X may have any planar shape and any planar size. The external connection pads P1 and the openings 61X may each have, for example, a circle planar shape having a diameter of approximately 200 μm to 300 μm.

### Second Wiring Structure 40

The second wiring structure 40 is formed on the upper surface of the first wiring structure 30. The second wiring structure 40 of the present embodiment is formed by sequentially stacking a wiring layer 41, an insulating layer 42, a wiring layer 43, an insulating layer 44, and a wiring layer 45 on the upper surface of the insulating layer 36, which is the uppermost layer of the first wiring structure 30.

The second wiring structure 40 has, for example, a higher wiring density than the first wiring structure 30. The second wiring structure 40 is a high-density wiring layer (fine wiring layer) having a higher wiring density than the first wiring structure 30. The wiring width and the wiring interval of the wiring layers 41, 43, and 45 are less than those of the wiring layers 31, 33, and 35. The second wiring structure 40 has a higher wiring density than the third wiring structure 50. The second wiring structure 40 is a high-density wiring layer having a higher wiring density than the third wiring structure 50. The wiring width and the wiring interval of the wiring layers 41, 43, and 45 are less than those of the wiring layers 51, 53, and 55. The line/space (L/S) of the wiring layers 41, 43, and 45 may be, for example, approximately 3 μm/3 μm to 8 μm/8 μm.

The material of the wiring layers 41, 43, and 45 may be, for example, copper or a copper alloy. The wiring layers 41, 43, and 45 are, for example, approximately equal in thickness to or thinner than the wiring layers 31, 33, and 35. The wiring layers 41, 43, and 45 may each have a thickness of, for example, approximately 8 μm to 15 μm.

The insulating layers 42 and 44 are insulating layers including a non-photosensitive resin as a main component. The main component of the insulating layers 42 and 44 may be, for example, a thermosetting non-photosensitive resin, such as an epoxy-based resin, an imide-based resin, a phenol-based resin, a cyanate-based resin, or the like. The insulating layers 42 and 44 may contain, for example, a filler, such as silica, alumina, or the like. The insulating layers 42 and 44 are, for example, each thinner than the core substrate 20. The thickness of each of the insulating layers 42 and 44 is, for example, less than the thickness of each of the insulating layers 32, 34, 36, 52, and 54. The insulating layers 42 and 44 may each have a thickness of, for example, approximately 1 μm to 10 μm. The insulating layers 42 and 44 may have the same thickness or different thicknesses.

The wiring layer 41 is formed on the upper surface of the insulating layer 36, which is the uppermost layer of the first wiring structure 30. The wiring layer 41 is connected to particular via wiring of the wiring layer 37. In the example illustrated in FIG. 1, the wiring layer 41 is connected to the first via wiring 37B. For example, the wiring layer 41 is formed integrally with the first via wiring 37B. The wiring layer 41 is electrically connected to the wiring layer 35 by the first via wiring 37B.

The insulating layer 42 is formed on the upper surface of the insulating layer 36, which is the uppermost layer of the first wiring structure 30, and covers the wiring layer 41. Through holes VH1 extend through the insulating layer 42 in the thickness-wise direction at given locations of the insulating layer 42, and expose parts of the upper surface of the wiring layer 37. For example, the through holes VH1 expose parts of the upper surface of the first via wiring 37A having a landless structure. Through holes VH2 extend through the insulating layer 42 in the thickness-wise direction at given locations of the insulating layer 42, and expose parts of the upper surface of the wiring layer 41.

The wiring layer 43 is formed on the upper surface of the insulating layer 42. Some parts of the wiring layer 43 are electrically connected to the first via wiring 37A by second via wiring V1 formed in the through holes VH1. Some parts of the wiring layer 43 are electrically connected to the wiring layer 41 by second via wiring V2 formed in the through holes VH2. For example, the wiring layer 43 is formed integrally with the second via wirings V1 and V2 that fill the through holes VH1 and VH2.

The insulating layer 44 is formed on the upper surface of the insulating layer 42 to cover the wiring layer 43. Through holes VH3 extend through the insulating layer 44 in the thickness-wise direction at given locations of the insulating layer 44, and expose parts of the upper surface of the wiring layer 43.

The through holes VH1, VH2, and VH3 are each tapered to have a diameter (opening width) that decreases from the upper side (closer to solder resist layer 60) toward the lower side (closer to first wiring structure 30) in FIG. 1. The through holes VH1, VH2, and VH3 each have a shape of, for example, an inverted truncated cone so that the upper open end has a larger diameter than the lower open end. The through holes VH1, VH2, and VH3 have, for example, a smaller opening diameter than the through holes 36X. The diameter of the upper open ends of the through holes VH1, VH2, and VH3 may be, for example, approximately 5 μm to 10 μm.

The wiring layer 45 is formed on the upper surface of the insulating layer 44. The wiring layer 45 is electrically connected to the wiring layer 43 by third via wiring V3 formed in the through holes VH3. For example, the wiring layer 45 is formed integrally with the third via wiring V3 that fills the through holes VH3. The wiring layer 45 includes, for example, pads P2. The pads P2 may have any planar shape and any planar size. The pads P2 may each have, for example, a circular planar shape having a diameter of approximately 20 μm to 30 μm. The pads P2 may have a pitch of, for example, approximately 40 μm to 60 μm. The pads P2 serve as electronic component mounting pads for electrical connection with an electronic component, such as the semiconductor chip or the like.

A surface-processed layer may be formed on surfaces (both upper and side surfaces or only upper surface) of the pads P2. The surface-processed layer may be an OSP film or a metal layer, such as an Au layer, an Ni layer/Au layer, an Ni layer/Pd layer/Au layer, or the like.

### Structure of Solder Resist Layer 60

The solder resist layer 60 is the outermost (here, the uppermost) insulating layer of the wiring substrate 10. The solder resist layer 60 is formed on the upper surface of the second wiring structure 40. In the example illustrated in FIG. 1, the solder resist layer 60 is formed on the upper surface of the insulating layer 44, which is the uppermost insulating layer of the second wiring structure 40. The solder resist layer 60 is an insulating layer including a photosensitive resin as a main component. The material of the solder resist layer 60 may be, for example, a photosensitive insulating resin including a phenol-based resin, a polyimide-based resin, or the like, as a main component. The solder resist layer 60 may contain, for example, a filler, such as silica, alumina, or the like.

The solder resist layer 60 is formed on the upper surface of the insulating layer 44 to expose the pads P2. For example, the solder resist layer 60 surrounds a mounting region in which an electronic component, such as a semiconductor chip, is mounted in plan view. In other words, the solder resist layer 60 includes an open portion 60X that exposes the upper surface of the second wiring structure 40 located in the mounting region. In plan view, the open portion 60X overlaps the mounting region. The open portion 60X extends through the solder resist layer 60 in the thickness-wise direction. The open portion 60X exposes the upper surface of the insulating layer 44 and the pads P2 located in the mounting region.

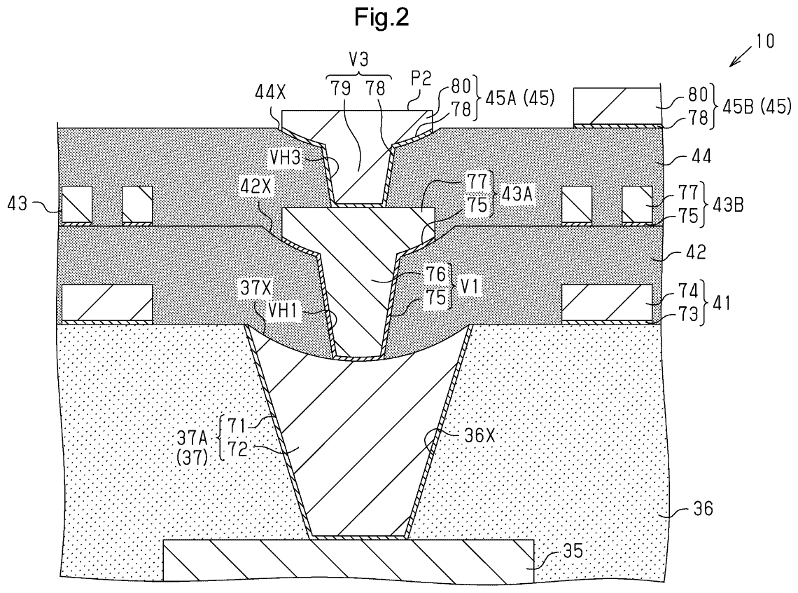

The structures of the wiring layer 37, the wiring layer 41, the insulating layer 42, the wiring layer 43, the insulating layer 44, and the wiring layer 45 will now be described with reference to FIG. 2. FIG. 2 illustrates the first via wiring 37A having a landless structure, the wiring layer 43 connected to the first via wiring 37A, and the wiring layer 45 connected to the wiring layer 43.

### Structure of First Via Wiring 37A

The upper surface of the first via wiring 37A is exposed from the insulating layer 36. The upper surface of the first via wiring 37A includes a first recess 37X recessed downward (toward wiring layer 35) from the upper surface of the insulating layer 36. The first recess 37X is, for example, formed in the entire upper surface of the first via wiring 37A.

The first recess 37X has a cross-sectional shape that is, for example, semicircular or semielliptical. The term “semicircular” as used in this specification is not limited to a semicircle obtained by bisecting a true circle and may include, for example, a shape having a relatively long arc or a relatively short arc. Further, the term “semielliptical” as used in this specification is not limited to a semi-ellipse obtained by bisecting an ellipse and may include, for example, a shape having a relatively long arc or a relatively short arc. The wall surface of the first recess 37X is curved in an arcuate manner. The wall surface of the first recess 37X is curved downward from the upper open end of the first recess 37X toward the planar center of the first recess 37X. The depth of the first recess 37X may be, for example, approximately 2 μm to 10 μm.

The first via wiring 37A includes, for example, a seed layer 71 formed on the wall surface of the through hole 36X, and a metal layer 72 formed at an inner side of the seed layer 71 in the through hole 36X.

The seed layer 71 covers the entire surface of the through hole 36X, that is, the entire wall surface of the through hole 36X, and the entire upper surface of the wiring layer 35 exposed at the bottom of the through hole 36X. The material of the seed layer 71 may be, for example, copper or a copper alloy. The seed layer 71 may be, for example, an electroless plating film formed by electroless plating or a sputtered film formed by sputtering.

The metal layer 72 fills, for example, the inner side of the seed layer 71 in the through hole 36X. The metal layer 72 covers the entire surface of the seed layer 71. The material of the metal layer 72 may be, for example, copper or a copper alloy. The metal layer 72 may be, for example, an electrolytic plating layer formed by electrolytic plating.

### Structure of Wiring Layer 41

The wiring layer 41 includes, for example, a seed layer 73 formed on the upper surface of the insulating layer 36, and a metal layer 74 formed on the upper surface of the seed layer 73.

The seed layer 73 of the wiring layer 41 is separate from the seed layer 71 of the first via wiring 37A. The seed layer 73 is, for example, electrically insulated from the seed layer 71. The material of the seed layer 73 may be, for example, copper or a copper alloy. The seed layer 73 is formed from, for example, the same material as the seed layer 71. The seed layer 73 has, for example, the same thickness as the seed layer 71. The seed layer 73 is, for example, formed simultaneously with the seed layer 71 by the same process. The seed layer 73 may be, for example, an electroless plating film or a sputtered film.

The metal layer 74 covers, for example, the entire upper surface of the seed layer 73. The metal layer 74 is, for example, electrically insulated from the metal layer 72 of the first via wiring 37A. The material of the metal layer 74 may be, for example, copper or a copper alloy. The metal layer 74 is formed from, for example, the same material as the metal layer 72. The metal layer 74 is, for example, formed simultaneously with the metal layer 72 by the same process. The metal layer 74 may be, for example, an electrolytic plating layer.

### Structure of Insulating Layer 42

The insulating layer 42 is formed on the upper surface of the insulating layer 36 to cover the upper surface of the first via wiring 37A and the upper surface and side surface of the wiring layer 41. For example, the insulating layer 42 fills the first recess 37X of the first via wiring 37A.

A second recess 42X is formed in the upper surface of the insulating layer 42, and is recessed toward the first via wiring 37A. The second recess 42X overlaps the first recess 37X in plan view.

The second recess 42X has a cross-sectional shape that is, for example, semicircular or semielliptical. The wall surface of the second recess 42X is curved in an arcuate manner. The wall surface of the second recess 42X is curved downward from the upper open end of the second recess 42X toward the planar center of the second recess 42X. The second recess 42X is, for example, shallower than the first recess 37X. The depth of the second recess 42X may be, for example, approximately 1 μm to 5 μm.

The second recess 42X may have any planar shape and any planar size. The planar shape of the second recess 42X is, for example, circular, which is the same as the first recess 37X (i.e., upper surface of first via wiring 37A). The second recess 42X has, for example, a smaller planar size than the first recess 37X. The diameter of the upper open end of the second recess 42X may be, for example, approximately 80 μm to 120 μm.

The through hole VH1 is formed in the wall surface of the second recess 42X to extend through the insulating layer 42 in the thickness-wise direction, and exposes part of the upper surface of the first via wiring 37A. The through hole VH1 exposes part of the wall surface of the first recess 37X. The through hole VH1 extends from the wall surface of the second recess 42X to the wall surface of the first recess 37X.

### Structure of Second Via Wiring V1

The second via wiring V1 fills the through hole VH1. The second via wiring V1 is directly connected to the upper surface of the first via wiring 37A having a landless structure. That is, the second via wiring V1 is directly connected to the upper surface of the first via wiring 37A without the wiring layer 41 having a land (reception pad). The second via wiring V1 is, for example, set to have a sufficiently smaller planar size than the first via wiring 37A. The planar size of the second via wiring V1 is, for example, set to approximately 0.1 to 0.5 times the planar size of the first via wiring 37A.

The second via wiring V1 is located immediately above the first via wiring 37A having a landless structure. The second via wiring V1 is directly placed upon the first via wiring 37A in a stacking direction (vertical direction in FIG. 2) of the wiring substrate 10, and is connected to the first via wiring 37A. That is, the first via wiring 37A and the second via wiring V1 form a stacked via structure. In this manner, the second via wiring V1, having a smaller diameter than the first via wiring 37A, is stacked immediately above the first via wiring 37A.

The second via wiring V1 includes, for example, a seed layer 75 formed on the wall surface of the through hole VH1, and a metal layer 76 formed at an inner side of the seed layer 75 in the through hole VH1.

The seed layer 75 covers the entire surface of the through hole VH1, that is, the entire wall surface of the through hole VH1, and the entire upper surface of the first via wiring 37A exposed at the bottom of the through hole VH1. The material of the seed layer 75 may be, for example, copper or a copper alloy. The seed layer 75 may be, for example, an electroless plating film or a sputtered film.

The metal layer 76 fills, for example, the inner side of the seed layer 75 in the through hole VH1. The metal layer 76 covers the entire surface of the seed layer 75. The material of the metal layer 76 may be, for example, copper or a copper alloy. The metal layer 76 may be, for example, an electrolytic plating layer.

### Structure of Wiring Layer 43

The wiring layer 43 includes, for example, a wiring layer 43A formed on the wall surface of the second recess 42X, and a wiring layer 43B formed on the upper surface of the insulating layer 42.

The wiring layer 43A is formed integrally with the second via wiring V1. The wiring layer 43A is, for example, a land. The lower surface of the wiring layer 43A is shaped in conformance with the wall surface of the second recess 42X. The lower surface of the wiring layer 43A is, for example, curved in an arcuate manner. The lower surface of the wiring layer 43A is, for example, curved downward toward the planar center of the second recess 42X. The lower surface of the wiring layer 43A is located downward from the lower surface of the wiring layer 43B.

The wiring layer 43A includes a lower part located inside the second recess 42X. The lower part of the wiring layer 43A faces the insulating layers 42 and 44 in a planar direction (sideward direction in FIG. 2) that is orthogonal to the stacking direction of the wiring substrate 10. The lower part of the wiring layer 43A does not face the wiring layer 43B in the planar direction. That is, the lower part of the wiring layer 43A faces only the insulating layers 42 and 44 in the planar direction.

The wiring layer 43A includes an upper part projecting upward from the upper surface of the insulating layer 42. The upper surface of the wiring layer 43A is located upward from the upper surface of the insulating layer 42. The upper surface of the wiring layer 43A is located downward from the upper surface of the wiring layer 43B. The upper part of the wiring layer 43A faces the insulating layer 44 and the wiring layer 43B in the planar direction.

The wiring layer 43A may have any planar shape and any planar size. The planar shape of the wiring layer 43A is, for example, circular. The wiring layer 43A has, for example, a smaller planar size than the first via wiring 37A. The wiring layer 43A has, for example, a smaller planar size than the second recess 42X. The diameter of the wiring layer 43A of the present example is smaller than the diameter of the upper open end of the second recess 42X. Therefore, the wall surface of the second recess 42X is partially exposed from the wiring layer 43A. The diameter of the wiring layer 43A may be, for example, approximately 30 μm to 60 μm.

The wiring layer 43B is, for example, located at a position that does not overlap the first via wiring 37A in plan view. The upper surface of the wiring layer 43B is located upward from the upper surface of the wiring layer 43A. The thickness of the wiring layer 43B is, for example, substantially the same as the thickness of the wiring layer 43A. The wiring layers 43A and 43B may each have a thickness of, for example, approximately 8 μm to 15 μm.

The wiring layers 43A and 43B each include, for example, the seed layer 75, and a metal layer 77 formed on the upper surface of the seed layer 75.

The seed layer 75 of the wiring layer 43A is formed integrally with the seed layer 75 of the second via wiring V1. The seed layer 75 of the wiring layer 43A covers the wall surface of the second recess 42X. The seed layer 75 of the wiring layer 43B covers the upper surface of the insulating layer 42.

The metal layer 77 covers, for example, the entire upper surface of the seed layer 75. The metal layer 77 of the wiring layer 43A is formed integrally with the metal layer 76 of the second via wiring V1. The material of the metal layer 77 may be, for example, copper or a copper alloy. The metal layer 77 is, for example, formed from the same material as the metal layer 76. The metal layer 77 may be, for example, an electrolytic plating layer.

### Structure of Insulating Layer 44

The insulating layer 44 is formed on the upper surface of the insulating layer 42 to cover the upper surface and side surface of the wiring layer 43. For example, the insulating layer 44 fills the second recess 42X exposed from the wiring layer 43A.

A third recess 44X may be formed in the upper surface of the insulating layer 44, and may be recessed toward the wiring layer 43A. The third recess 44X overlaps the second recess 42X in plan view. The third recess 44X overlaps the first recess 37X in plan view.

The third recess 44X has a cross-sectional shape that is, for example, semicircular or semielliptical. The wall surface of the third recess 44X is curved in an arcuate manner. The wall surface of the third recess 44X is curved downward from the upper open end of the third recess 44X toward the planar center of the third recess 44X. The third recess 44X is, for example, shallower than the second recess 42X. The depth of the third recess 44X may be, for example, approximately 0.5 μm to 3 μm.

The third recess 44X may have any planar shape and any planar size. The planar shape of the third recess 44X is, for example, circular, which is the same as the first recess 37X. The third recess 44X has, for example, a smaller planar size than the second recess 42X. The diameter of the upper open end of the third recess 44X may be, for example, approximately 50 μm to 100 μm.

The through hole VH3 is formed in the wall surface of the third recess 44X to extend through the insulating layer 44 in the thickness-wise direction, and exposes part of the upper surface of the wiring layer 43A. The through hole VH3 extends from the wall surface of the third recess 44X to the upper surface of the wiring layer 43A.

### Structure of Third Via Wiring V3

The third via wiring V3 fills the through hole VH3. The planar size of the third via wiring V3 is, for example, set to be substantially the same as or smaller than the planar size of the second via wiring V2.

The third via wiring V3 is, for example, located immediately above the second via wiring V1. The first via wiring 37A, the second via wiring V1, and the third via wiring V3 are directly placed one upon the other in the stacking direction of the wiring substrate 10, and are connected to each other. That is, the first via wiring 37A, the second via wiring V1, and the third via wiring V3 form a stacked via structure.

The third via wiring V3 includes, for example, a seed layer 78 formed on the wall surface of the through hole VH3, and a metal layer 79 formed at an inner side of the seed layer 78 in the through hole VH3.

The seed layer 78 covers the entire surface of the through hole VH3, that is, the entire wall surface of the through hole VH3, and the entire upper surface of the wiring layer 43A exposed at the bottom of the through hole VH3. The material of the seed layer 78 may be, for example, copper or a copper alloy. The seed layer 78 may be, for example, an electroless plating film or a sputtered film.

The metal layer 79 fills, for example, the inner side of the seed layer 78 in the through hole VH3. The metal layer 79 covers the entire surface of the seed layer 78. The material of the metal layer 79 may be, for example, copper or a copper alloy. The metal layer 79 may be, for example, an electrolytic plating layer.

### Structure of Wiring Layer 45

The wiring layer 45 includes, for example, a wiring layer 45A formed on the wall surface of the third recess 44X, and a wiring layer 45B formed on the upper surface of the insulating layer 44.

The wiring layer 45A is formed integrally with the third via wiring V3. The wiring layer 45A is, for example, a land. The lower surface of the wiring layer 45A is shaped in conformance with the wall surface of the third recess 44X. The lower surface of the wiring layer 45A is, for example, curved in an arcuate manner. The lower surface of the wiring layer 45A is, for example, curved downward toward the planar center of the third recess 44X. The lower surface of the wiring layer 45A is located downward from the lower surface of the wiring layer 45B.

The wiring layer 45A includes a lower part located inside the third recess 44X. The lower part of the wiring layer 45A faces the insulating layer 44 in the planar direction. The lower part of the wiring layer 45A does not face the wiring layer 45B in the planar direction. That is, the lower part of the wiring layer 45A faces only the insulating layer 44 in the planar direction.

The wiring layer 45A includes an upper part projecting upward from the upper surface of the insulating layer 44. The upper surface of the wiring layer 45A is located upward from the upper surface of the insulating layer 44. The upper surface of the wiring layer 45A is located downward from the upper surface of the wiring layer 45B. The upper part of the wiring layer 45A faces the wiring layer 45B in the planar direction.

The wiring layer 45A may have any planar shape and any planar size. The planar shape of the wiring layer 45A is, for example, circular. The wiring layer 45A has, for example, a smaller planar size than the first via wiring 37A. The planar size of the wiring layer 45A is, for example, substantially the same as or smaller than the planar size of the third recess 44X. The diameter of the wiring layer 45A of the present example is smaller than the diameter of the upper open end of the third recess 44X. Therefore, the wall surface of the third recess 44X is partially exposed from the wiring layer 45A. The diameter of the wiring layer 45A may be, for example, approximately 30 μm to 60 μm.

The wiring layer 45B is, for example, located at a position that does not overlap the first via wiring 37A in plan view. The upper surface of the wiring layer 45B is located upward from the upper surface of the wiring layer 45A. The thickness of the wiring layer 45B is, for example, substantially the same as the thickness of the wiring layer 45A. The wiring layers 45A and 45B may each have a thickness of, for example, approximately 8 μm to 15 μm.

The wiring layers 45A and 45B each include, for example, the seed layer 78, and a metal layer 80 formed on the upper surface of the seed layer 78.

The seed layer 78 of the wiring layer 45A is formed integrally with the seed layer 78 of the third via wiring V3. The seed layer 78 of the wiring layer 45A covers the wall surface of the third recess 44X. The seed layer 78 of the wiring layer 45B covers the upper surface of the insulating layer 44.

The metal layer 80 covers, for example, the entire upper surface of the seed layer 78. The metal layer 80 of the wiring layer 45A is formed integrally with the metal layer 79 of the third via wiring V3. The material of the metal layer 80 may be, for example, copper or a copper alloy. The metal layer 80 is formed from, for example, the same material as the metal layer 79. The metal layer 80 may be, for example, an electrolytic plating layer.

### Method for Manufacturing Wiring Substrate 10

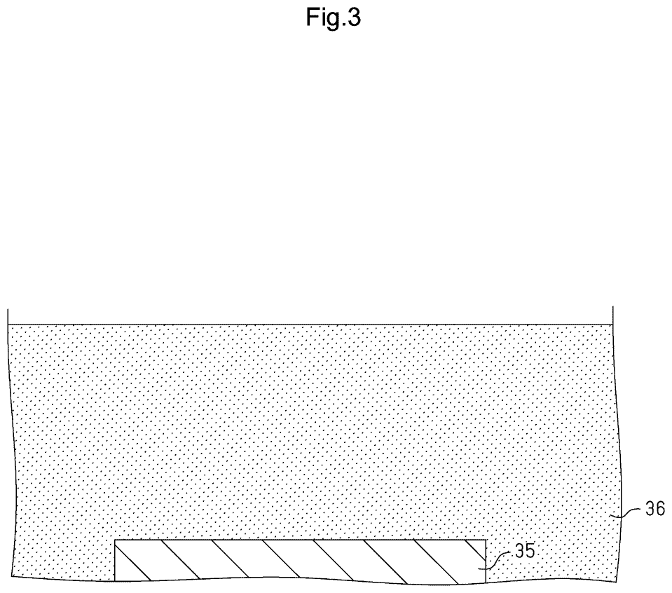

A method for manufacturing the wiring substrate 10 will now be described with reference to FIGS. 3 to 18. The described method manufactures the structural body illustrated in FIG. 2.

In the step illustrated in FIG. 3, the wiring layer 35 is formed, and the insulating layer 36 is formed to cover the upper surface and side surface of the wiring layer 35. The wiring layer 35 and the insulating layer 36 may be manufactured by a known manufacturing process. Therefore, the process will not be described in detail.

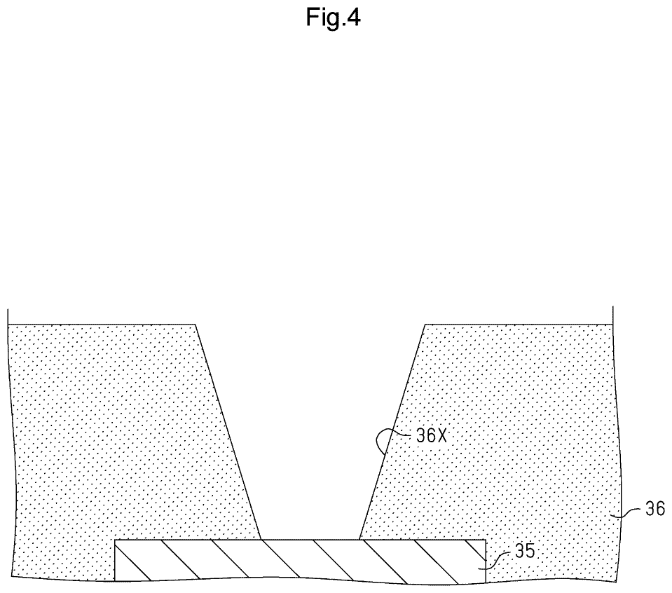

In the step illustrated in FIG. 4, the through holes 36X are formed in given locations of the insulating layer 36 to expose parts of the upper surface of the wiring layer 35. The through holes 36X may be formed by, for example, laser drilling using CO₂ laser, UV-YAG laser, or the like.

When the through holes 36X are formed by laser drilling, a desmearing process is performed to remove resin smears from the surface of the wiring layer 35 exposed at the bottom of the through holes 36X. The desmearing process of this step may be, for example, wet etching using a potassium permanganate solution or the like.

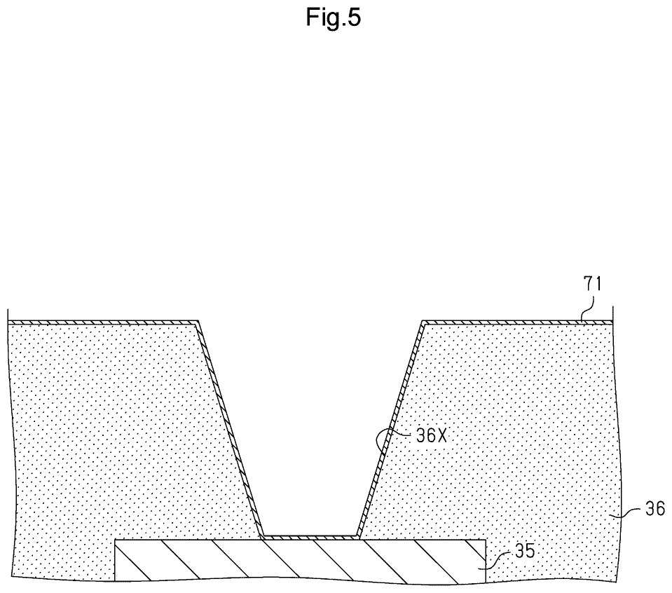

In the step illustrated in FIG. 5, the seed layer 71 is formed to cover the entire surface of the insulating layer 36, including the wall surface of the through holes 36X. In this example, the seed layer 71 continuously covers the entire upper surface of the insulating layer 36, the entire wall surface of the through holes 36X, and the entire upper surface of the wiring layer 35 exposed at the bottom of the through holes 36X. The seed layer 71 may be formed by, for example, electroless plating or sputtering. When forming the seed layer 71 by electroless plating, electroless copper plating may be performed to form the seed layer 71 having a single-layer structure (Cu layer). Alternatively, when forming the seed layer 71 by sputtering, titanium is first sputtered and deposited on the upper surface of the insulating layer 36 and the wall surface of the through holes 36X to form a Ti film that covers the upper surface of the insulating layer 36 and the wall surface of the through holes 36X. Then, copper is sputtered and deposited on the Ti film to form a Cu film. This forms the seed layer 71 having a two-layer structure (Ti film/Cu film).

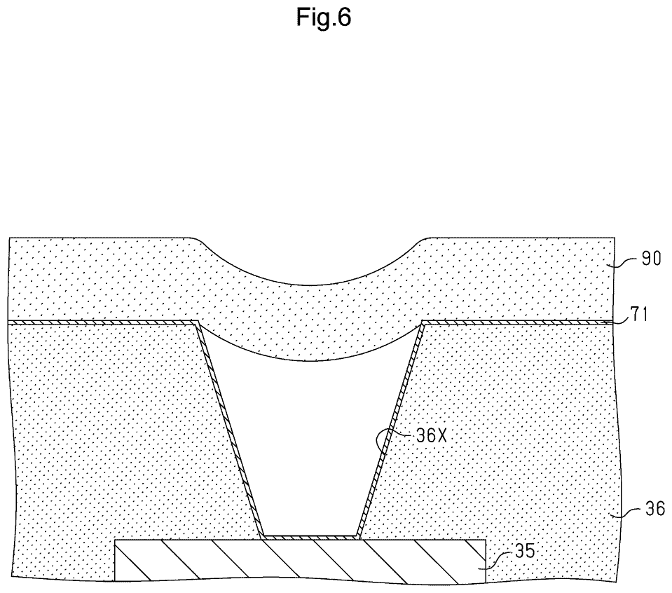

In the step illustrated in FIG. 6, a resist layer 90 is formed on the seed layer 71. The material of the resist layer 90 may be, for example, a material that is resistant to the plating process performed in the following step. The resist layer 90 may be, for example, a photosensitive dry film resist. The photosensitive dry film resist may be, for example, a dry film resist of a novolac-based resin, an acrylic-based resin, or the like. When using a photosensitive dry film resist as the resist layer 90, the resist layer 90 may be formed on the upper surface of the seed layer 71 by laminating the upper surface of the seed layer 71 with the dry film by thermocompression bonding. In this case, the resist layer 90 closes the opening of the through holes 36X. The parts of the resist layer 90 that close the opening of the through holes 36X may sag.

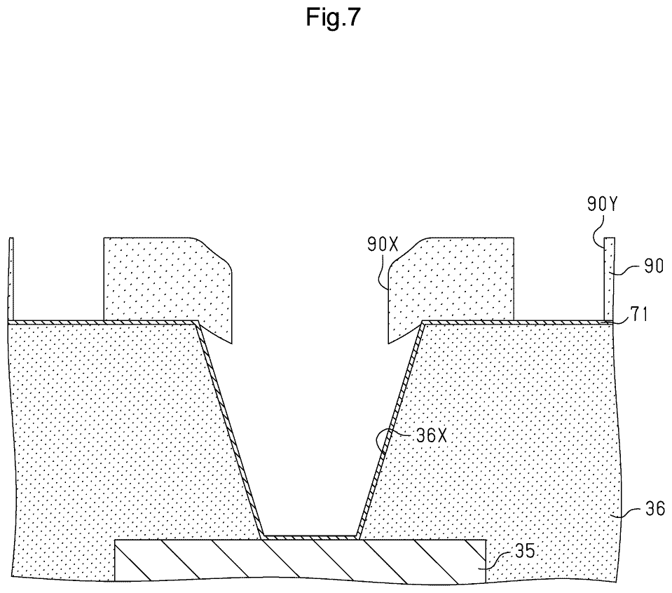

In the step illustrated in FIG. 7, opening patterns 90X and 90Y are formed in the resist layer 90. For example, photolithography is performed to pattern the resist layer 90 to form the opening patterns 90X and 90Y. The opening pattern 90X overlaps the through holes 36X in plan view. The diameter of the opening pattern 90X is set to be smaller than the diameter of the upper open end of the through holes 36X. Therefore, the resist layer 90 projects inward from each through hole 36X, such that the resist layer 90 forms a ring shape above the through hole 36X. Further, the opening pattern 90Y exposes parts of the upper surface of the seed layer 71 corresponding to regions in which the wiring layer 41, illustrated in FIG. 2, is formed.

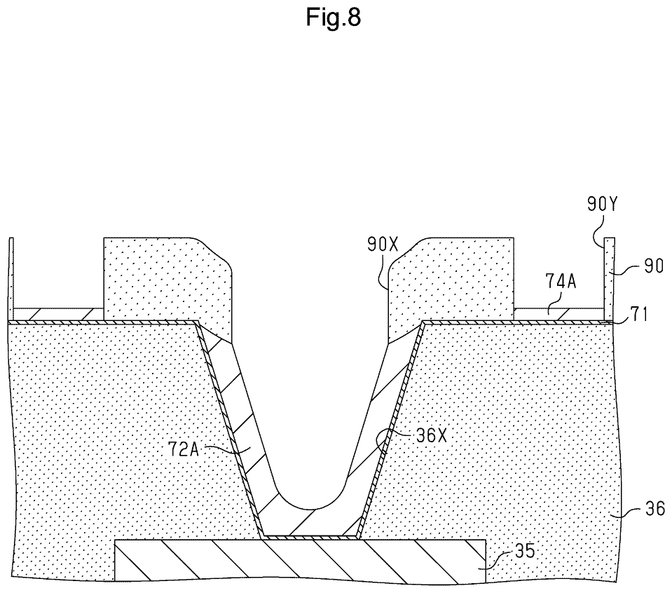

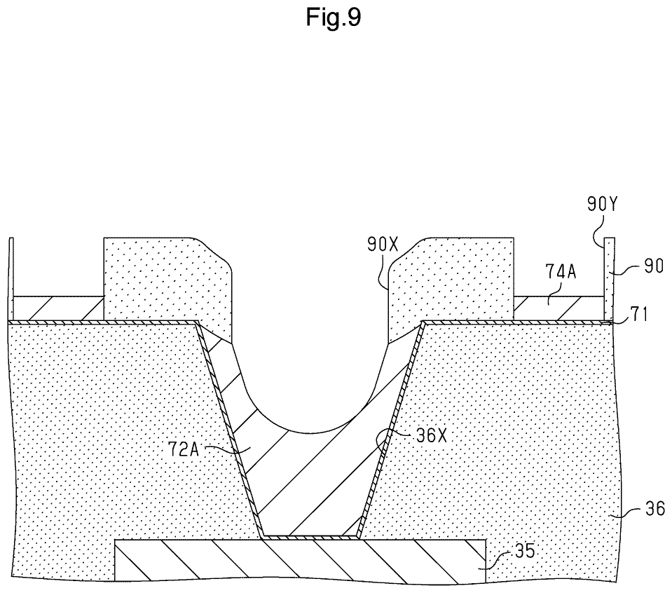

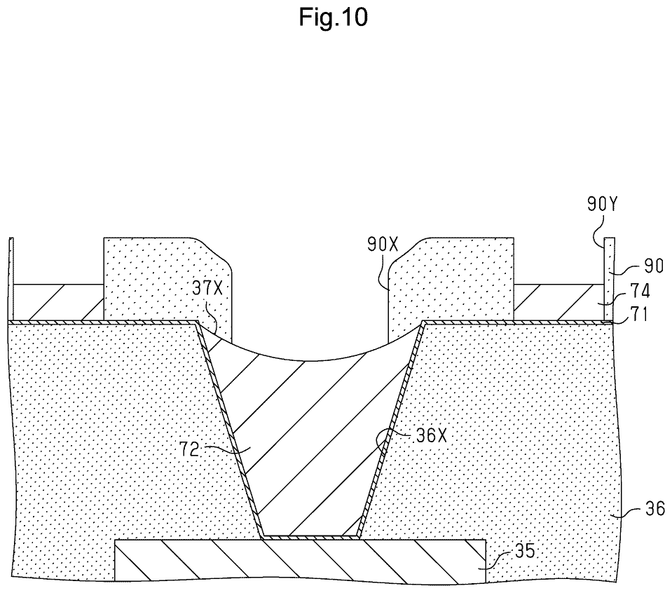

In the step illustrated in FIGS. 8 to 10, electrolytic plating (here, electrolytic Cu plating) is performed on the seed layer 71, exposed from the resist layer 90, by using the resist layer 90 as a plating mask and using the seed layer 71 as a plating power feeding layer. As illustrated in FIG. 8, an electrolytic Cu plating film 72A is deposited on the seed layer 71, which is exposed from the resist layer 90 and formed on the wall surface of the through holes 36X. When the electrolytic Cu plating is continued, the electrolytic Cu plating film 72A is deposited in an isotropic manner. In this case, since the ring-shaped part of the resist layer 90 projects inward from each through hole 36X, stirring of a plating solution may not be as sufficient as that in normal via-filling plating. Accordingly, a reaction inhibiter added to the plating solution may be less effective at the upper part of the electrolytic Cu plating film 72A. However, the resist layer 90 covers the upper part of the electrolytic Cu plating film 72A, thereby limiting the deposition efficiency at the upper part of the electrolytic Cu plating film 72A. This avoids preferential deposition of the Cu at the upper part of the electrolytic Cu plating film 72A, such that a lid will not form to close the upper part of the electrolytic Cu plating film 72A. As illustrated in FIG. 9, when the electrolytic Cu plating is further continued, the electrolytic Cu plating film 72A is preferentially deposited at the bottom of the through hole 36X. As the electrolytic Cu plating film 72A fills the bottom of the through hole 36X, the plating solution is sufficiently stirred, and therefore the reaction inhibiter becomes effective at the upper part of the electrolytic Cu plating film 72A. As illustrated in FIG. 10, when the electrolytic Cu plating is further continued, the metal layer 72 is formed to fill the inner side of the seed layer 71 in the through hole 36X, and the first recess 37X is formed in the upper surface of the metal layer 72. In this step, as long as the opening pattern 90X of the resist layer 90 has a sufficiently large opening width, the electrolytic Cu plating film 72A will not grow preferentially at the upper part of the through hole 36X to form a lid. The diameter of the opening pattern 90X may be, for example, approximately 0.7 to 0.8 times the diameter of the upper open end of the through hole 36X.

In addition, as illustrated in FIG. 8, an electrolytic Cu plating film 74A is deposited on the upper surface of the seed layer 71, which is exposed from the opening pattern 90Y of the resist layer 90. As illustrated in FIG. 9, when the electrolytic Cu plating is continued, the electrolytic Cu plating film 74A is deposited in an isotropic manner. As illustrated in FIG. 10, when the electrolytic Cu plating is further continued, the metal layer 74 may be formed on the upper surface of the seed layer 71, which is exposed from the opening pattern 90Y.

As described above, the step illustrated in FIGS. 8 to 10 simultaneously forms the metal layer 72 only in the through holes 36X, and the metal layer 74 in the opening pattern 90Y.

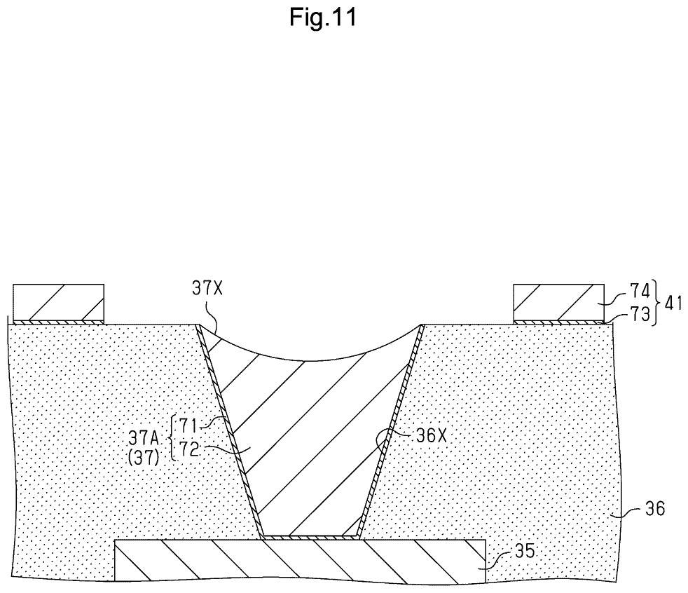

In the step illustrated in FIG. 11, the resist layer 90 illustrated in FIG. 10 is removed using an alkaline stripping solution (e.g., organic amine-based stripping solution, caustic soda, acetone, ethanol, or the like).

Then, etching is performed using the metal layers 72 and 74 as etching masks to remove unnecessary portions of the seed layer 71. This step separates the seed layer 71 formed on the wall surface of the through holes 36X from the seed layer 71 (hereafter, seed layer 73) formed on the upper surface of the insulating layer 36. The seed layer 71 and the metal layer 72 formed in the through holes 36X form the first via wiring 37A, and the seed layer 73 and the metal layer 74 formed on the upper surface of the insulating layer 36 form the wiring layer 41. As described above, the manufacturing method of the present embodiment simultaneously forms the first via wiring 37A having a landless structure, and the wiring layer 41 formed on the insulating layer 36.

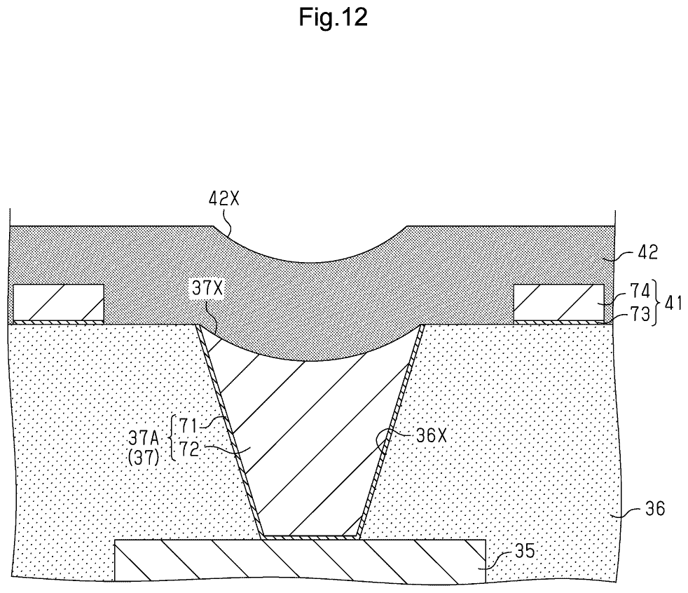

In the step illustrated in FIG. 12, the insulating layer 42 is formed to cover the upper surface of the insulating layer 36, the upper surface of the first via wiring 37A, and the wiring layer 41. The insulating layer 42 fills the first recess 37X of the first via wiring 37A. The second recess 42X is formed in the upper surface of the insulating layer 42 at a position that overlaps the first recess 37X in plan view. In other words, the insulating layer 42 includes the second recess 42X in its upper surface. When using a resin film as the insulating layer 42, the upper surface of the insulating layer 36 may be laminated with the resin film. Then, the resin film may be heated at a curing temperature or higher (e.g., approximately 130° C. to 200° C.) while being pressed so that the resin film is cured to form the insulating layer 42. When using a liquid or a paste of insulating resin as the insulating layer 42, the liquid or paste of insulating resin may be applied to the upper surface of the insulating layer 36 by spin coating or the like. Then, the applied insulating resin may be heated at a curing temperature or higher so that the insulating resin is cured to form the insulating layer 42. The insulating resin forming the insulating layer 42 may be, for example, a thermosetting resin, such as an epoxy-based resin, a polyimide-based resin, or the like.

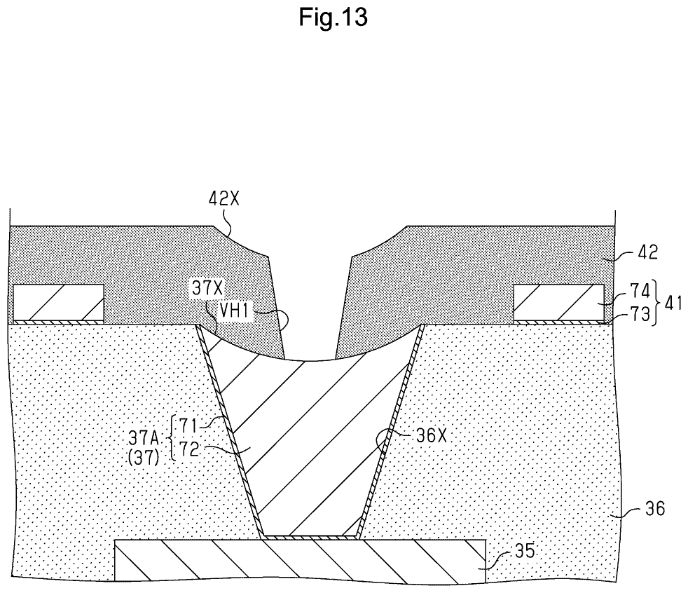

In the step illustrated in FIG. 13, the through holes VH1 are formed in given locations of the insulating layer 42 to expose parts of the upper surface of the first via wiring 37A. Each through hole VH1 extends from the wall surface of the second recess 42X to the wall surface of the first recess 37X of the first via wiring 37A. The through holes VH1 may be formed by, for example, laser drilling. The diameter of the through holes VH1 is sufficiently smaller than the diameter of the through holes 36X. Therefore, it is preferred that the through holes VH1 be formed using an excimer laser, which is suitable for microfabrication.

When the through holes VH1 are formed by laser drilling, a desmearing process is performed to remove resin smears from the surface of the first via wiring 37A exposed at the bottom of the through holes VH1. The desmearing process of this step may be, for example, a dry desmearing process using a carbon tetrafluoride (CF₄) gas or the like.

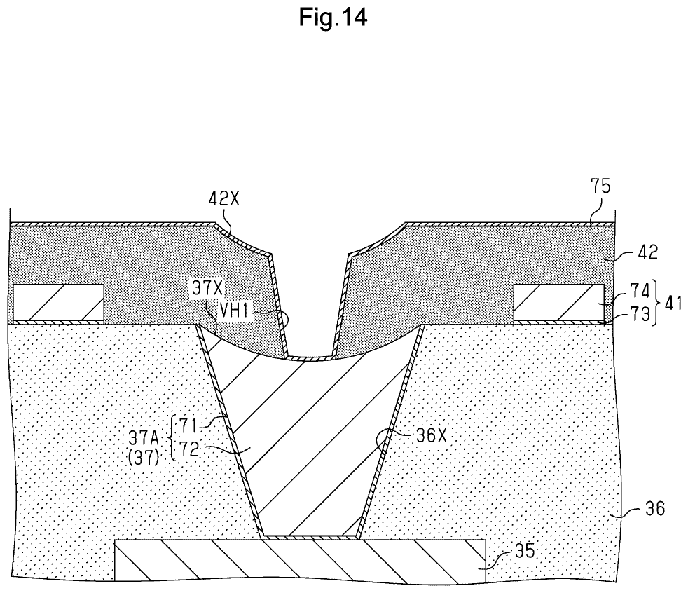

In the step illustrated in FIG. 14, the seed layer 75 is formed to cover the entire upper surface of the insulating layer 42, the entire wall surface of the second recesses 42X, the entire wall surface of the through holes VH1, and the entire upper surface of the first via wiring 37A exposed at the bottom of the through holes VH1. The seed layer 75 may be formed by, for example, sputtering or electroless plating.

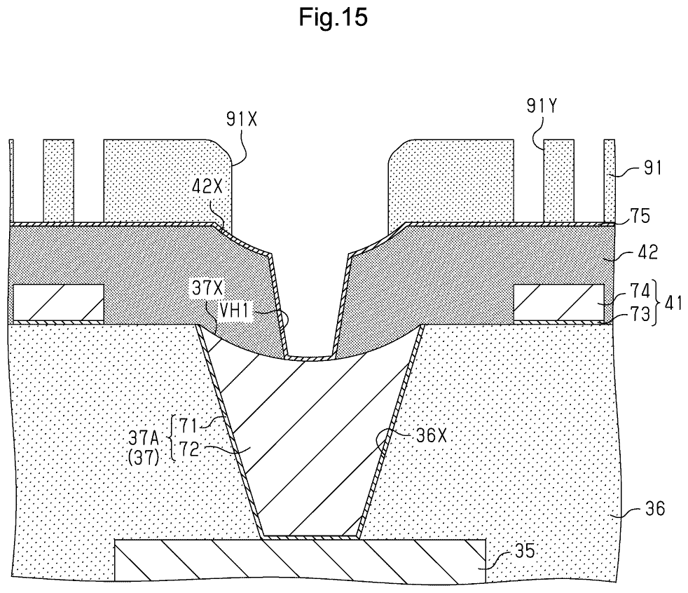

In the step illustrated in FIG. 15, a resist layer 91 including opening patterns 91X and 91Y is formed on the upper surface of the seed layer 75, in the same manner as the steps illustrated in FIGS. 6 and 7. The opening pattern 91X overlaps the second recesses 42X in plan view. The diameter of the opening pattern 91X is set to be smaller than the diameter of the upper open end of the second recesses 42X. Therefore, the resist layer 91 projects inward from each second recess 42X, such that the resist layer 91 forms a ring shape above the second recess 42X. Further, the opening pattern 91Y exposes parts of the upper surface of the seed layer 75 corresponding to the regions in which the wiring layer 43B, illustrated in FIG. 2, is formed.

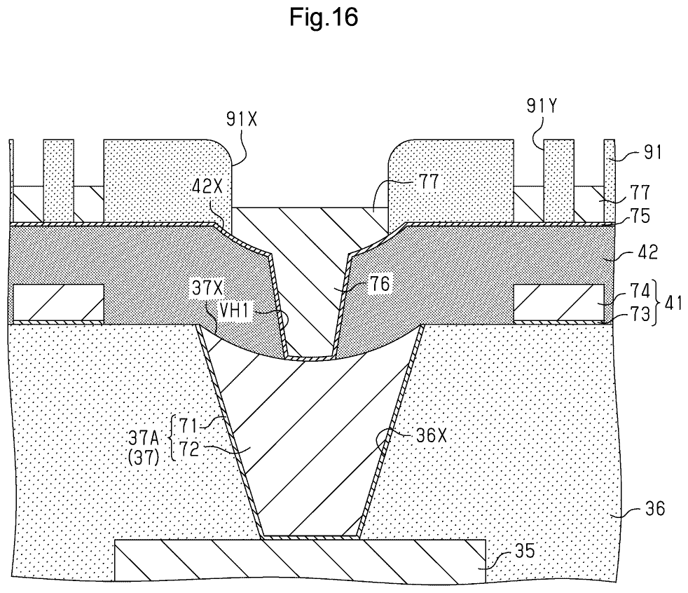

In the step illustrated in FIG. 16, electrolytic plating (here, electrolytic Cu plating) is performed on the seed layer 75, exposed from the opening patterns 91X and 91Y of the resist layer 91, by using the resist layer 91 as a plating mask and using the seed layer 75 as a plating power feeding layer. As a result, the metal layer 76 fills the inner side of the seed layer 75 in the through holes VH1, and the metal layer 77 is formed on the seed layer 75 exposed from the opening pattern 91X. Also, the metal layer 77 is formed on the seed layer 75 exposed from the opening pattern 91Y.

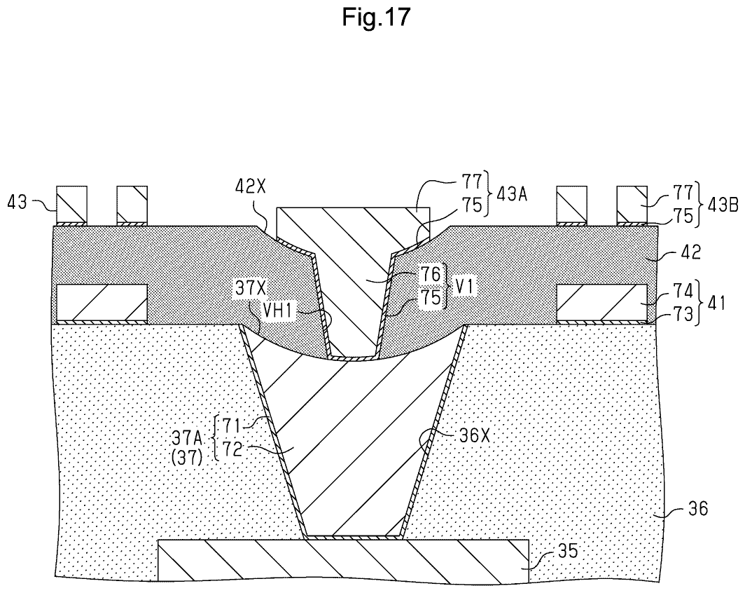

In the step illustrated in FIG. 17, the resist layer 91 illustrated in FIG. 16 is removed using an alkali stripping solution. Then, etching is performed using the metal layer 77 as an etching mask to remove unnecessary portions of the seed layer 75. In this step, the seed layer 75 and the metal layer 76 formed in the through holes VH1 form the second via wiring V1, and the seed layer 75 and the metal layer 77 formed on the wall surface of the second recesses 42X form the wiring layer 43A. Also, the seed layer 75 and the metal layer 77 formed on the upper surface of the insulating layer 42 form the wiring layer 43B. In this case, the upper surface of the wiring layer 43A, which is formed integrally with the second via wiring V1 and serving as a land, is recessed downward from the upper surface of the wiring layer 43B.

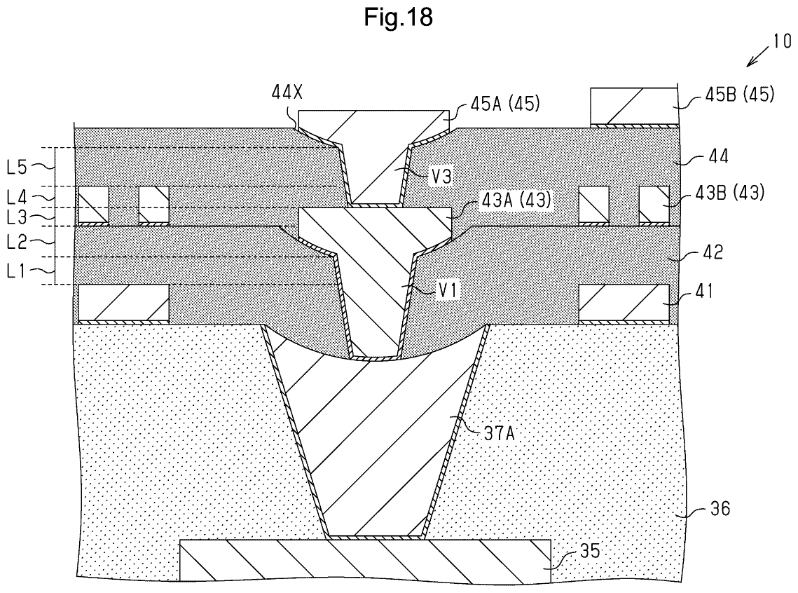

In the step illustrated in FIG. 18, a procedure similar to that illustrated in FIGS. 12 to 17 is performed to sequentially stack the insulating layer 44 including the third recesses 44X, and the wiring layer 45 including the wiring layers 45A and 45B, on the upper surface of the insulating layer 42.

In the present embodiment, the wiring layer 35 is an example of a first wiring layer. The insulating layer 36 is an example of a first insulating layer. The through hole 36X is an example of a first through hole. The insulating layer 42 is an example of a second insulating layer. The wiring layer 43A is an example of a second wiring layer. The wiring layer 43B is an example of a third wiring layer. The wiring layer 41 is an example of a fourth wiring layer. The insulating layer 44 is an example of a third insulating layer. The wiring layer 45A is an example of a fifth wiring layer. The wiring layer 45B is an example of a sixth wiring layer. The through hole VH1 is an example of second through hole. The through hole VH2 is an example of third through hole. The seed layer 71 is an example of a first seed layer. The metal layer 72 is an example of a first metal layer. The seed layer 73 is an example of a second seed layer. The metal layer 74 is an example of a second metal layer. The opening pattern 90X is an example of a first opening pattern. The opening pattern 90Y is an example of a second opening pattern.

### Advantages

The present embodiment has the following advantages.

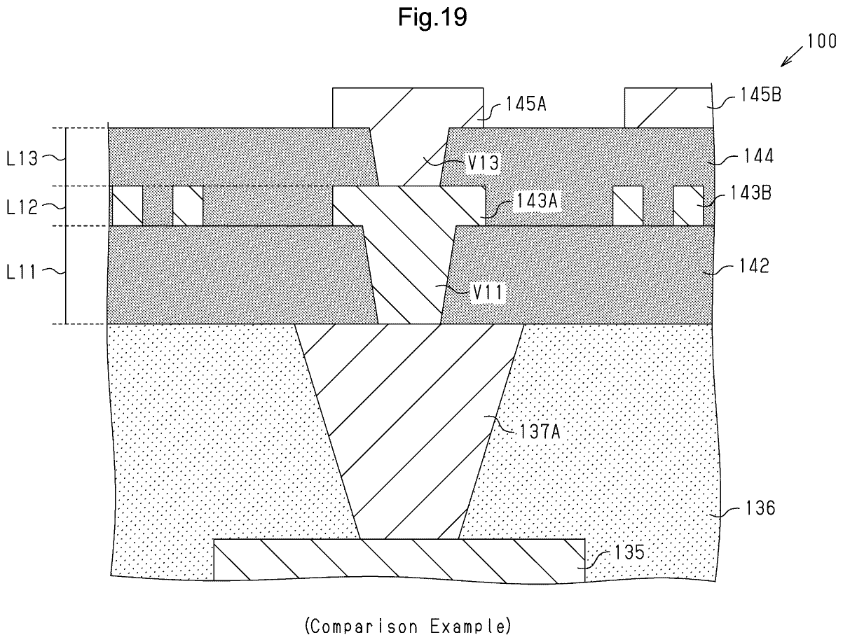

(1) The structure and problems of a wiring substrate 100 of a comparative example will now be described with reference to FIG. 19.

The wiring substrate 100 includes a wiring layer 135, an insulating layer 136 covering the wiring layer 135, a first via wiring 137A extending through the insulating layer 136 in a thickness-wise direction, and an insulating layer 142 formed on the upper surface of the insulating layer 136. The first via wiring 137A has a landless structure. The wiring substrate 100 further includes a second via wiring V11 extending through the insulating layer 142 in the thickness-wise direction, a wiring layer 143A formed integrally with the second via wiring V11, and a wiring layer 143B formed on the upper surface of the insulating layer 142. The second via wiring V11 is connected to the first via wiring 137A. The wiring substrate 100 further includes an insulating layer 144 formed on the upper surface of the insulating layer 142 to cover the wiring layers 143A and 143B, and a third via wiring V13 extending through the insulating layer 144 in the thickness-wise direction. The third via wiring V13 is connected to the wiring layer 143A. The wiring substrate 100 further includes a wiring layer 145A formed integrally with the third via wiring V13, and a wiring layer 145B formed on the upper surface of the insulating layer 144. In the wiring substrate 100, the wiring layer 143A, which is formed integrally with the second via wiring V11, is coplanar with the wiring layer 143B. Therefore, the lower surface of the wiring layer 143A is coplanar with the lower surface of the wiring layer 143B, and the upper surface of the wiring layer 143A is coplanar with the upper surface of the wiring layer 143B.

In the wiring substrate 100 described above, a difference in copper remaining ratio with respect to the horizontal direction is relatively large in the stacking direction of the wiring substrate 100 (vertical direction in FIG. 19). The copper remaining ratio refers to a ratio of an area of a conductor layer (in this example, copper layer) to an area of an insulating layer.

In particular, in layer L11, only the second via wiring V11 is the copper layer. Therefore, the copper remaining ratio of layer L11 is relatively low. In layer L12, the wiring layers 143A and 143B are the copper layers. In this case, the wiring layers 143A and 143B extend in the horizontal direction (planar direction). Accordingly, the copper remaining ratio of layer L12 is higher than the copper remaining ratio of layer L11. The difference in copper remaining ratio between layer L11 and layer L12 is relatively large. In layer L13, only the third via wiring V13 is the copper layer. Therefore, the copper remaining ratio of layer L13 is relatively low. The difference in copper remaining ratio between layer L12 and layer L13 is relatively large. In this manner, in the wiring substrate 100, the difference in copper remaining ratio is relatively large between adjacent layers L11, L12, and L13.

When the difference in copper remaining ratio is relatively large between layers L11 and L12, the portion connecting the wiring layer 143A (land) and the second via wiring V11 may receive a relatively large stress. This stress may break the portion connecting the wiring layer 143A and the second via wiring V11. Similarly, when the difference in copper remaining ratio is relatively large between layers L12 and L13, the portion connecting the wiring layer 143A and the third via wiring V13 may receive a relatively large stress. This stress may break the portion connecting the wiring layer 143A and the third via wiring V13.

In contrast, as illustrated in FIG. 18, in the wiring substrate 10 of the present embodiment, the wiring layer 43A, which is formed integrally with the second via wiring V1, is offset downward from the wiring layer 43B. With this structure, a difference in the copper remaining ratio with respect to the horizontal direction is relatively small in the stacking direction of the wiring substrate 10, as compared to the wiring substrate 100 of the comparative example. In particular, in layer L1, only the second via wiring V1 is the copper layer. Therefore, the copper remaining ratio of layer L1 is relatively low. In layer L3, the wiring layers 43A and 43B are the copper layers. The wiring layers 43A and 43B extend in the horizontal direction (planar direction). Accordingly, the copper remaining ratio of layer L3 is higher than the copper remaining ratio of layer L1. In this case, the difference in copper remaining ratio between layers L1 and L3 is approximately as large as that between layers L11 and L12. However, the wiring substrate 10 includes layer L2 located between layers L1 and L3. In this layer L2, only the wiring layer 43A is the copper layer. The copper remaining ratio of layer L2 is higher than the copper remaining ratio of layer L1 and is lower than the copper remaining ratio of layer L3. Therefore, the difference in remaining copper rate between layers L1 and L2 is lower than that between layers L11 and L12. Furthermore, the difference in copper remaining ratio between layers L2 and L3 is lower than that between layers L11 and L12.

As described above, the difference in copper remaining ratio between layers L1 and L2 is relatively small, and the difference in copper remaining ratio between layers L2 and L3 is relatively small. This may reduce, for example, the stress applied to the portion connecting the wiring layer 43A (land) and the second via wiring V1. Therefore, the stress is less likely to break the portion connecting the wiring layer 43A and the second via wiring V1. As a result, the reliability of electrical connection is improved between the wiring layer 43A and the second via wiring V1.

(2) In layer L5 of the wiring substrate 10, only the third via wiring V3 is the copper layer. Therefore, the copper remaining ratio of layer L5 is relatively low. In this case, the difference in copper remaining ratio between layers L5 and L3 is approximately as large as that between layers L12 and L13. However, the wiring substrate 10 includes layer L4 located between layers L3 and L5. In this layer L4, the wiring layer 43B and the third via wiring V3 are the copper layers. The copper remaining ratio of layer L4 is lower than the copper remaining ratio of layer L3 and is higher than the copper remaining ratio of layer L5. Therefore, the difference in remaining copper rate between layers L3 and L4 is lower than that between layers L12 and L13. Furthermore, the difference in copper remaining ratio between layers L4 and L5 is lower than that between layers L12 and L13.

As described above, the difference in copper remaining ratio between layers L3 and L4 is relatively small, and the difference in copper remaining ratio between layers L4 and L5 is relatively small. This may reduce, for example, the stress applied to the portion connecting the wiring layer 43A (land) and the third via wiring V3. Therefore, the stress is less likely to break the portion connecting the wiring layer 43A and the third via wiring V3. As a result, the reliability of electrical connection is improved between the wiring layer 43A and the third via wiring V3.

(3) The upper surface of the wiring layer 43A is located downward from the upper surface of the wiring layer 43B. The third via wiring V3 is connected to the upper surface of the wiring layer 43A. With this structure, the portion connecting the wiring layer 43A and the third via wiring V3 is offset downward from the upper surface of the wiring layer 43B. Accordingly, the portion connecting the wiring layer 43A and the third via wiring V3 faces the upper part of the wiring layer 43B in the planar direction. Therefore, a difference in thermal expansion coefficient may reduce the stress applied to the bottom of the third via wiring V3, as compared to a structure in which the portion connecting the wiring layer 43A and the third via wiring V3 faces only the insulating layer 44 in the planar direction.

(4) In a typical wiring substrate, in order to form via wiring having a landless structure, a land that is formed integrally with via wiring filling a through hole is removed by performing etching or the like. This method increases the amount of etching as it requires etching of the entire land. When the amount of etching becomes relatively large, a seed layer formed on the wall surface of the through hole may be overlay etched due to a difference in etching rate between the seed layer, which is an electroless plating layer formed on the wall surface of the through hole, and an electrolytic plating layer which is formed at an inner side of the seed layer. When the seed layer is overly etched, delamination may occur between the via wiring and an insulating layer.

In contrast, in the manufacturing method of the present embodiment, the opening pattern 90X having a smaller opening width than the upper open end of the through holes 36X is arranged in the resist layer 90, which is formed on the seed layer 71. The opening pattern 90X is located at a position that overlaps the through holes 36X in plan view. Further, electrolytic plating is performed using the resist layer 90 as a plating mask and using the seed layer 71 as a power feeding layer, so as to fill the inner side of the seed layer 71 in the through holes 36X and form the metal layer 72 having the first recesses 37X in the upper surface. This method forms the first via wiring 37A having a landless structure without needing to remove lands by etching or the like. Since etching is not necessary to remove lands, the seed layer 71 formed on the wall surface of the through holes 36X will not be overly etched. This appropriately avoids delamination between the first via wiring 37A and the insulating layer 36.

(5) The manufacturing process is simplified by eliminating the need to remove lands by etching.

(6) When etching is performed to remove the entire land, the wiring layer 41 formed on the upper surface of the insulating layer 36 needs to be masked to protect the wiring layer 41 from the etching. In contrast, in the present embodiment, etching is not necessary to remove lands, thereby eliminating the need to mask the wiring layer 41.

### MODIFIED EXAMPLES

The above embodiment may be modified as described below. The above embodiment and the following modifications may be combined as long as there is no technical contradiction.

In the second wiring structure 40 of the above embodiment, the numbers of wiring layers and insulating layers, the wiring layout, or the like may be modified or changed in any manner.

In the second wiring structure 40 of the above embodiment, the insulating layer 44, the third via wiring V3, and the wiring layer 45 may be omitted.

In the second wiring structure 40 of the above embodiment, the wiring layer 41 may be omitted.

In the above embodiment, the insulating layers 42 and 44 are insulating layers including a non-photosensitive resin as a main component. Instead, for example, the insulating layers 42 and 44 may be insulating layers including a photosensitive resin as a main component.

In the first wiring structure 30 of the above embodiment, the numbers of wiring layers and insulating layers, the wiring layout, or the like may be modified or changed in any manner. For example, the first wiring structure 30 may be changed to a structure including a single wiring layer and a single insulating layer.

The structure of the first via wiring 37A in the above embodiment may be changed. For example, the first via wiring 37A may include a projection that projects upward from the upper surface of the insulating layer 36. For example, the projection that projects upward from the upper surface of the insulating layer 36 may be formed on the edge of the upper surface of the first via wiring 37A. The projection amount of the projection may be, for example, approximately 1 μm to 1.5 μm.

In the third wiring structure 50 of the above embodiment, the numbers of wiring layers and insulating layers, the wiring layout, or the like may be modified or changed in any manner. For example, the third wiring structure 50 may be changed to a structure including a single wiring layer and a single insulating layer.

In the above embodiment, the solder resist layers 60 and 61 are described as examples of protective insulating layers located at the outermost layers of the wiring substrate 10. Such protective insulating layers may be formed from any type of photosensitive insulating resin.

The solder resist layers 60 and 61 of the above embodiment may be omitted.

The through-electrodes 21 of the above embodiment may be changed to, for example, through-electrodes that completely fill the through holes 20X with a plating metal layer (e.g., Cu layer) or the like.

### CLAUSES

This disclosure further encompasses the following embodiments.

1. A method for manufacturing a wiring substrate, the method including:
forming a first insulating layer covering an upper surface and a side surface of a first wiring layer;
forming a first through hole extending through the first insulating layer in a thickness-wise direction, the first through hole exposing part of the upper surface of the first wiring layer;
forming a first via wiring having a landless structure, the first via wiring filling the first through hole and including a first recess formed in an upper surface of the first via wiring, the first recess being recessed downward from an upper surface of the first insulating layer;
forming a second insulating layer on the upper surface of the first insulating layer, the second insulating layer filling the first recess and including a second recess formed in an upper surface of the second insulating layer, the second recess overlapping the first recess in plan view;
forming a second through hole extending from the second recess to the first recess;
forming a second via wiring filling the second through hole; and
forming a second wiring layer on a wall surface of the second recess, and a third wiring layer on the upper surface of the second insulating layer, the second wiring layer being formed integrally with the second via wiring,
in which the second wiring layer has an upper surface located downward from an upper surface of the third wiring layer.

2. The method according to clause 1, in which the forming the first via wiring includes:
forming a seed layer continuously covering an entirety of a wall surface of the first through hole and an entirety of the upper surface of the first insulating layer;
forming a resist layer on an upper surface of the seed layer to close an opening of the first through hole;
forming a first opening pattern on a portion of the resist layer overlapping the first through hole in plan view, the first opening pattern having an opening width that is smaller than that of an upper open end of the first through hole; and
forming a first metal layer on the seed layer located in the first through hole by performing electrolytic plating using the resist layer as a plating mask and using the seed layer as a plating power feeding layer, the first metal layer filling the first through hole and including the first recess in an upper surface of the first metal layer.

3. The method according to clause 2, in which
the forming the first via wiring includes forming a fourth wiring layer on the upper surface of the first insulating layer simultaneously with the first via wiring,
the forming the first opening pattern includes forming a second opening pattern on the resist layer, the second opening patter exposing part of the upper surface of the seed layer covering the upper surface of the first insulating layer,
the forming the first metal layer includes forming, by performing the electrolytic plating, a second metal layer on the upper surface of the seed layer exposed from the second opening pattern,
the seed layer formed on the wall surface of the first through hole and the first metal layer form the first via wiring, and
the seed layer formed on the upper surface of the first insulating layer and the second metal layer form the fourth wiring layer.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate, comprising:
a first wiring layer;
a first insulating layer covering an upper surface and a side surface of the first wiring layer;
a first through hole extending through the first insulating layer in a thickness-wise direction and exposing part of the upper surface of the first wiring layer;
a first via wiring having a landless structure and filling the first through hole;
a first recess formed in an upper surface of the first via wiring and recessed downward from an upper surface of the first insulating layer;
a second insulating layer formed on the upper surface of the first insulating layer and filling the first recess;
a second recess formed in an upper surface of the second insulating layer and overlapping the first recess in plan view;
a second through hole extending from the second recess to the first recess;
a second via wiring filling the second through hole;
a second wiring layer formed on a wall surface of the second recess and formed integrally with the second via wiring; and
a third wiring layer formed on the upper surface of the second insulating layer, wherein
the second via wiring has a planar size that is smaller than that of the first via wiring, and
the second wiring layer has an upper surface located downward from an upper surface of the third wiring layer.

2. The wiring substrate according to claim 1, wherein the second wiring layer has a planar size that is smaller than that of the first via wiring.

3. The wiring substrate according to claim 1, further comprising a fourth wiring layer formed on the upper surface of the first insulating layer,
wherein the second insulating layer covers the fourth wiring layer.

4. The wiring substrate according to claim 1, wherein the second recess has a planar size that is smaller than that of the first recess.

5. The wiring substrate according to claim 1, wherein the second wiring layer has a planar size that is smaller than that of the second recess.

6. The wiring substrate according to claim 1, wherein
the second wiring layer includes a lower part located inside the second recess, and an upper part projecting upward from the second recess, and
the upper surface of the second wiring layer is defined by an upper surface of the upper part.

7. The wiring substrate according to claim 6, further comprising a third insulating layer formed on the upper surface of the second insulating layer, the third insulating layer filling the second recess and covering the second wiring layer and the third wiring layer,
wherein the lower part of the second wiring layer faces the second insulating layer and the third insulating layer in a direction orthogonal to a thickness-wise direction of the second wiring layer.

8. The wiring substrate according to claim 3, wherein
the first via wiring includes a first seed layer formed on a wall surface of the first through hole, and a first metal layer formed on the first seed layer and filling the first through hole,
the fourth wiring layer includes a second seed layer formed on the upper surface of the first insulating layer, and a second metal layer formed on an upper surface of the second seed layer,
the second seed layer and the first seed layer are formed from a same material, and
the second metal layer and the first metal layer are formed from a same material.

9. The wiring substrate according to claim 1, further comprising:
a third insulating layer formed on the upper surface of the second insulating layer and covering the second wiring layer and the third wiring layer;
a third through hole extending through the third insulating layer in a thickness-wise direction and exposing part of the upper surface of the second wiring layer; and
a third via wiring filling the third through hole.

10. The wiring substrate according to claim 9, further comprising:
a third recess formed in an upper surface of the third insulating layer and overlapping the second recess in plan view;
a fifth wiring layer formed on a wall surface of the third recess and formed integrally with the third via wiring; and
a sixth wiring layer formed on the upper surface of the third insulating layer, wherein
the third through hole extends from the third recess to the upper surface of the second wiring layer, and
the fifth wiring layer has an upper surface located downward from an upper surface of the sixth wiring layer.

11. The wiring substrate according to claim 1, further comprising:
a first wiring structure including the first wiring layer, the first insulating layer, and the first via wiring; and
a second wiring structure including the second insulating layer, the second via wiring, the second wiring layer, and the third wiring layer,
wherein the second wiring structure has a wiring density that is higher than that of the first wiring structure.
